(19) United States
(12) Patent Application Publication
(10) Pub. No.: US 2015/0318451 A1
(43) Pub. Date: Nov. 5, 2015

(54) LIGHT EMITTING DEVICE

(71) Applicant: Kabushiki Kaisha Toshiba, Minato-ku (JP)

(72) Inventors: Kunio ISHIDA, Fuchu (JP); Keiko Albessard, Yokohama (JP); Yasushi Hattori, Kawasaki (JP); Masahiro Kato, Naka (JP)

(73) Assignee: Kabushiki Kaisha Toshiba, Minato-ku (JP)

(21) Appl. No.: 14/696,766

(22) Filed: Apr. 27, 2015

(30) Foreign Application Priority Data
Apr. 30, 2014 (JP) 2014-094082

(51) Int. Cl. H01L 33/50; H01L 33/56

(52) U.S. Cl. CPC H01L 33/504; H01L 33/56

(57) ABSTRACT

A light emitting device of an embodiment includes a light emitting element emitting near-ultraviolet light or blue light as exciting light; and a yellow color conversion layer including a yellow phosphor and a resin, the yellow phosphor represented by formula (1) and being capable of converting the exciting light to yellow light, the resin surrounding the yellow phosphor, the yellow color conversion layer containing the yellow phosphor at a volume concentration of at most 7%, the yellow color conversion layer having a region whose cross section parallel to a light emitting surface of the light emitting element has an area larger than the light emitting surface,

(Sr₁₋ₓ₁Ceₓ₁)ₐ₁AlSi_{b1}O_{c1}N_{d1} (1)

wherein x1, a1, b1, c1, and d1 satisfy following relations: 0<x1≦0.1, 0.6<a1<0.95, 2.0<b1<3.9, 0<c1<0.45, and 4.0<d1<5.0.

### CROSS-REFERENCE TO RELATED APPLICATION

This application is based upon and claims the benefit of priority from Japanese Patent Application No. 2014-094082, filed on Apr. 30, 2014, the entire contents of which are incorporated herein by reference.

### FIELD

Embodiments described herein relate generally to a light emitting device.

### BACKGROUND

Light emitting devices using a light emitting diode (LED) are mainly composed of a combination of the LED as an exciting light source and a phosphor. Light emission of a variety of colors is possible by varying the combination.

Light emitting devices using light emitting diodes are used in portable devices, PC peripherals, OA equipment, a variety of switches, backlight light sources, and a variety of displays such as display boards. These light emitting devices are strongly demanded to have high efficiency and high color rendering capacity.

### BRIEF DESCRIPTION OF THE DRAWINGS

FIG. 1 is a schematic cross-sectional view of a light emitting device of a first embodiment;

FIGS. 2A and 2B are illustrations of the mechanism of the light emitting device of the first embodiment;

FIG. 3 is a schematic cross-sectional view of a light emitting device of a second embodiment;

FIG. 4 is a schematic cross-sectional view of a light emitting device of a third embodiment;

FIG. 5 is a schematic cross-sectional view of a light emitting device of a fourth embodiment;

FIG. 6 is a schematic cross-sectional view of a light emitting device of a fifth embodiment;

FIG. 7 is a schematic cross-sectional view of a light emitting device of a sixth embodiment;

FIG. 8 is a schematic cross-sectional view of a light emitting device of a seventh embodiment;

FIG. 9 is a schematic cross-sectional view of a light emitting device of an eighth embodiment;

FIG. 10 is a schematic cross-sectional view of a light emitting device of a ninth embodiment; and

FIG. 11 is a schematic cross-sectional view of a light emitting device of a tenth embodiment.

### DETAILED DESCRIPTION

A light emitting device of an embodiment includes a light emitting element emitting near-ultraviolet light or blue light as exciting light; and

a yellow color conversion layer including a yellow phosphor and a resin, the yellow phosphor represented by formula (1) and being capable of converting the exciting light to yellow light, the resin surrounding the yellow phosphor, the yellow color conversion layer containing the yellow phosphor at a volume concentration of at most 7%, the yellow color conversion layer having a region whose cross section parallel to a light emitting surface of the light emitting element has an area larger than the light emitting surface,

(Sr₁₋ₓ₁Ceₓ₁)ₐ₁AlSi_{b1}O_{c1}N_{d1} (1)

wherein x1, a1, b1, c1, and d1 satisfy following relations: 0<x1≦0.1, 0.6<a1<0.95, 2.0<b1<3.9, 0<c1<0.45, and 4.0<d1<5.0.

In the description, the peak wavelength of light emitted by the light emitting element or the phosphor means a wavelength at which the intensity distribution of light emitted by the light emitting element or the phosphor has the maximum. The peak intensity means the intensity of light at the peak wavelength. The peak wavelength and the light intensity can be measured using a known light spectrum analyzer, light power meter, or the like.

In the description, “white light” means light with a color temperature in the range of the light bulb color (2,700 K) to the daylight color (6,500 K) unless otherwise specified.

In the description, “near-ultraviolet light” means light with a maximum peak wavelength of 200 nm to less than 410 nm. “Blue light” means light with a maximum peak wavelength of 410 nm to less than 480 nm. “Green light” means light with a maximum peak wavelength of 480 nm to less than 530 nm. “Yellow light” means light with a maximum peak wavelength of 530 nm to less than 600 nm. “Red light” means light with a maximum peak wavelength of 600 nm to less than 760 nm.

Hereinafter, embodiments will be described with reference to the drawings.

### First Embodiment

Alight emitting device of an embodiment includes a light emitting element emitting near-ultraviolet light or blue light as exciting light and a yellow color conversion layer including a yellow phosphor and a resin. The yellow phosphor is represented by below formula (1) and is capable of converting the exciting light to yellow light. The resin surrounds the yellow phosphor. The yellow color conversion layer contains the yellow phosphor at a volume concentration of 7% or less, the yellow color conversion layer having a region whose cross section parallel to a light emitting surface of the light emitting element has an area larger than the light emitting surface.

(Sr₁₋ₓ₁Ceₓ₁)ₐ₁AlSi_{b1}O_{c1}N_{d1} (1)

(In formula (1), x1, a1, b1, c1, and d1 satisfy the following relations: 0<x1≦0.1, 0.6<a1<0.95, 2.0<b1<3.9, 0<c1<0.45, and 4.0<d1<5.0.)

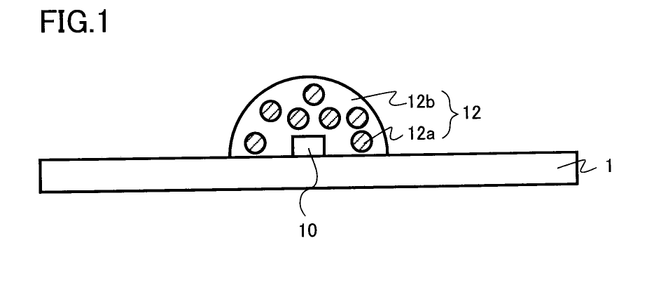

FIG. 1 is a schematic cross-sectional view of the light emitting device of this embodiment. This light emitting device is a white light emitting device.

The light emitting device of this embodiment includes a substrate 1, a light emitting element 10, and a color conversion layer (first color conversion layer) 12. The light emitting element 10 is mounted on the substrate 1. For example, a highly reflective material is used to form the substrate 1.

The light emitting element 10 is connected to wiring (not shown) on the substrate 1. A driving current is externally supplied to the light emitting element 10 through the wiring to emit light.

For example, the light emitting element 10 is configured to emit blue light with a peak wavelength of 410 nm to less than 480 nm as exciting light. The exciting light is emitted from the upper surface of the light emitting element 10.

The light emitting element 10 is, for example, a blue light emitting diode (LED). The blue LED is, for example, an AlGaInN LED having a GaInN light emitting layer. The blue LED has, for example, a square shape whose upper surface has a side of 300 μm.

The color conversion layer 12 is provided on the optical path of the exciting light emitted from the light emitting element 10. In this embodiment, the color conversion layer 12 is dome-shaped. And the color conversion layer 12 is disposed in such a way that the upper and side surfaces of the light emitting element 10 are covered with the color conversion layer 12 and the light emitting element 10 is embedded in the color conversion layer 12. The color conversion layer 12 has a region whose cross section parallel to the light emitting surface of the light emitting element 10 has an area larger than the light emitting surface. In this case, the light emitting surface of the light emitting element 10 corresponds to the upper surface of the light emitting element 10 in FIG. 1.

The color conversion layer 12 includes a plurality of phosphor (yellow phosphor) particles 12a and a resin 12b surrounding the phosphor particles 12a. The thickness of the color conversion layer 12 is, for example, from 0.1 mm to 3.0 mm. The thickness of the color conversion layer 12 can be determined by cutting the light emitting device and actually measuring the cross-section by microscopic observation or the like.

In this embodiment, the phosphor particles 12a have a chemical composition expressed by formula (1) below, which represents a yellow phosphor capable of converting the exciting light to yellow light.

(Sr₁₋ₓ₁Ceₓ₁)ₐ₁AlSi_{b1}O_{c1}N_{d1} (1)

(In formula (1), x1, a1, b1, c1, and d1 satisfy the following relations: 0<x1≦0.1, 0.6<a1<0.95, 2.0<b1<3.9, 0<c1<0.45, and 4.0<d1<5.0.)

In this embodiment, the phosphor particles 12a emit yellow light with a peak wavelength of 530 nm to less than 600 nm. In this embodiment, the phosphor particles 12a are made of an oxynitride phosphor containing silicon (Si), aluminum (Al), and strontium (Sr), which is what is called a sialon phosphor. This phosphor has a crystal structure substantially the same as that of Sr₂Si₇Al₃ON₁₃ and is activated with Ce. The sialon phosphor emits light with high efficiency.

The phosphor particles 12a preferably have a particle size of 1 μm to 25 μm. The phosphor particles 12a more preferably have a particle size of 3 μm or more, even more preferably 5 μm or more.

The particle size of the phosphor particles 12a can be measured with a commercially available particle size distribution analyzer. For example, Laser Diffraction HELOS & RODOS manufactured by Sympatec GmbH may be used. When phosphor particles form an aggregate, the measurement should be performed after the lump is crushed in such a way that the reduction in quantum efficiency is less than 5%. In this embodiment, the particle size means the median size (D50).

The resin 12b forms a matrix in the color conversion layer 12. The phosphor particles 12a are dispersed in the resin 12b. The resin 12b is a transparent resin. The resin is, for example, a silicone resin.

The volume concentration of the phosphor (yellow phosphor) particles 12a in the color conversion layer 12 is 7% or less. To calculate the volume concentration, the volume of the phosphor particles 12a is used as a numerator, and the volume of the color conversion layer 12 is used as a denominator. For example, using a microphotograph, the area occupied by the phosphor particles 12a in a 0.1 mm square area of the color conversion layer 12 is measured and then divided by 0.01 mm² to calculate the volume concentration of the phosphor particles.

Next, the mechanism and effect of the light emitting device of this embodiment will be described.

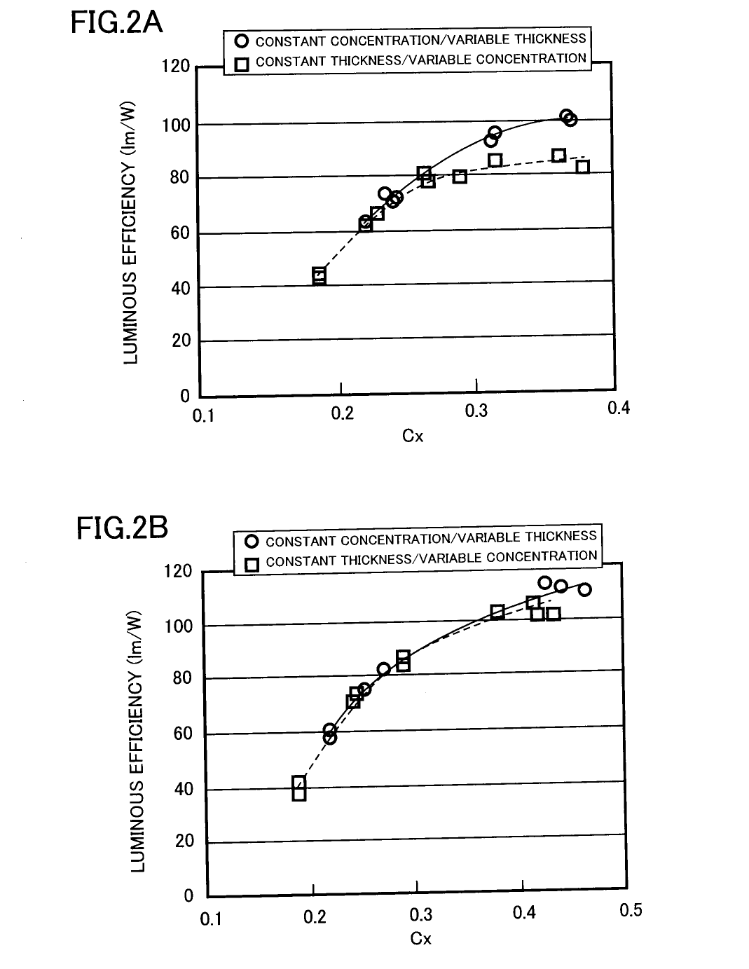

FIGS. 2A and 2B are illustrations of the mechanism of the light emitting device of this embodiment. FIG. 2A is a graph showing the relationship between the luminous efficiency and the x-coordinate (Cx) on the CIE chromaticity diagram when the sialon phosphor of this embodiment is used. FIG. 2B is a graph showing the relationship between the luminous efficiency and the x-coordinate (Cx) on the chromaticity diagram when a YAG phosphor of a comparative embodiment is used.

In the cases of both of this embodiment and the comparative embodiment, blue light is used as the exciting light, and the amount of the yellow phosphor in the color conversion layer is changed by the two methods below when the luminous efficiency is evaluated. In the first method, the thickness of the color conversion layer is varied while the volume concentration of the phosphor in the color conversion layer is kept constant (“CONSTANT CONCENTRATION/VARIABLE THICKNESS” in FIGS. 2A and 2B). In the second method, the volume concentration of the phosphor in the color conversion layer is varied while the thickness of the color conversion layer is kept constant (“CONSTANT THICKNESS/VARIABLE CONCENTRATION” in FIGS. 2A and 2B).

The sialon phosphor used is (Sr_{0.97}Ce_{0.03})_{0.67}AlSi_{2.3}O_{0.33}N_{4.3}.

It is apparent that in the case of the sialon phosphor of this embodiment, the luminous efficiency in the first method becomes different from that in the second method as Cx increases from about 0.26 and a higher luminous efficiency is obtained in the first method, namely, the method of increasing the amount of the yellow phosphor while keeping the volume concentration of the yellow phosphor constant. For example, when Cx is 0.33, corresponding to white light, the luminous efficiency in the first method differs by at least 7% from that in the second method. When Cx is 0.33, the volume concentration of the yellow phosphor is 7% in the first method and 14% in the second method.

On the other hand, in the case of the YAG phosphor of the comparative embodiment, no significant difference is observed between the first and second methods.

As shown above, the sialon phosphor of this embodiment exhibits a specific tendency, which is not exhibited by the YAG phosphor of the comparative embodiment. This is considered to be associated with the scattering of the exciting light by the phosphor.

As the volume concentration of the phosphor in the color conversion layer 12 increases, the solid angle at which the light emitting element sees the color conversion layer increases, so that the density of the exciting light in the color conversion layer increases, which increases the probability that the exciting light will be scattered by the phosphor. Therefore, the optical feedback to the light emitting element 10 increases, so that the luminous efficiency decreases.

The amount of cerium (Ce) as an activator per unit volume is smaller in the sialon phosphor than in the YAG phosphor. Therefore, a larger volume is required of the sialon phosphor to emit the same intensity of yellow light. This suggests that the scattering of the exciting light should be more likely to become significant when the sialon phosphor is used than when the YAG phosphor is used.

In the case of the sialon phosphor, the volume concentration of the yellow phosphor in the color conversion layer 12 is preferably 7% or less in order to suppress the reduction of the luminous efficiency. The volume concentration is more preferably 6% or less, even more preferably 4% or less.

The volume concentration of the yellow phosphor in the color conversion layer 12 is preferably 0.2% or more so that the color conversion layer 12 can be prevented from being too thick and the size of the light emitting device can be kept suitable for practical use.

In order to suppress the reduction of the luminous efficiency, the volume concentration of the phosphor is preferably set relatively low also when the light emitting device emits light with the same chromaticity. Therefore, the amount of cerium (Ce) as an activator is preferably set relatively large, and the relation 0.05≦x1≦0.1 is preferred.

As shown in FIG. 2A, the difference in luminous efficiency between the first and second methods becomes significant in the region where white light is emitted using blue light as the exciting light. Therefore, the light emitting device preferably emit light with a chromaticity of (0.30≦Cx≦0.48, 0.30≦Cy≦0.44) when the chromaticity is expressed as (Cx, Cy) coordinates on the CIE chromaticity diagram and when blue light is used as the exciting light should.

According to the light emitting device of this embodiment, the volume concentration of the yellow phosphor in the color conversion layer is limited to a certain level or lower. Therefore, the luminous efficiency reduction caused by the scattering of the exciting light is suppressed. This makes it possible to provide a light emitting device with an improved luminous efficiency.

The light emitting element 10 configured to emit blue light as exciting light has been described herein as an example. Alternatively, a light emitting element configured to emit near-ultraviolet light as exciting light may be used. In this case, the light emitting device emits yellow light instead of white light.

The chromaticity of the light emitted by the light emitting device of this embodiment can be adjusted to the desired chromaticity by appropriately controlling the wavelength and intensity of the exciting light, the thickness of the color conversion layer, and the amount of the phosphor under conditions where the volume concentration of the phosphor particles in the color conversion layer is limited to 7% or less.

### Second Embodiment

The light emitting device of this embodiment includes a light emitting element emitting near-ultraviolet light or blue light as exciting light, and a green color conversion layer including a green phosphor and a resin, the green phosphor represented by formula (2) and being capable of converting the exciting light to green light, the resin surrounding the green phosphor, the green color conversion layer containing the green phosphor at a volume concentration of 7% or less. This device has the same features as those of the first embodiment, except that it has the green color conversion layer containing the green phosphor instead of the yellow color conversion layer containing the yellow phosphor. Therefore, a detailed description of the same features as those of the first embodiment will be omitted.

(Sr₁₋ₓ₂Euₓ₂)ₐ₂AlSi_{b2}O_{c2}N_{d2} (2)

(In formula (2), x2, a2, b2, c2, and d2 satisfy the following relations: 0<x2≦0.2, 0.93<a2<1.3, 4.0<b2<5.8, 0.6<c2<1.0, and 6.0<d2<11.)

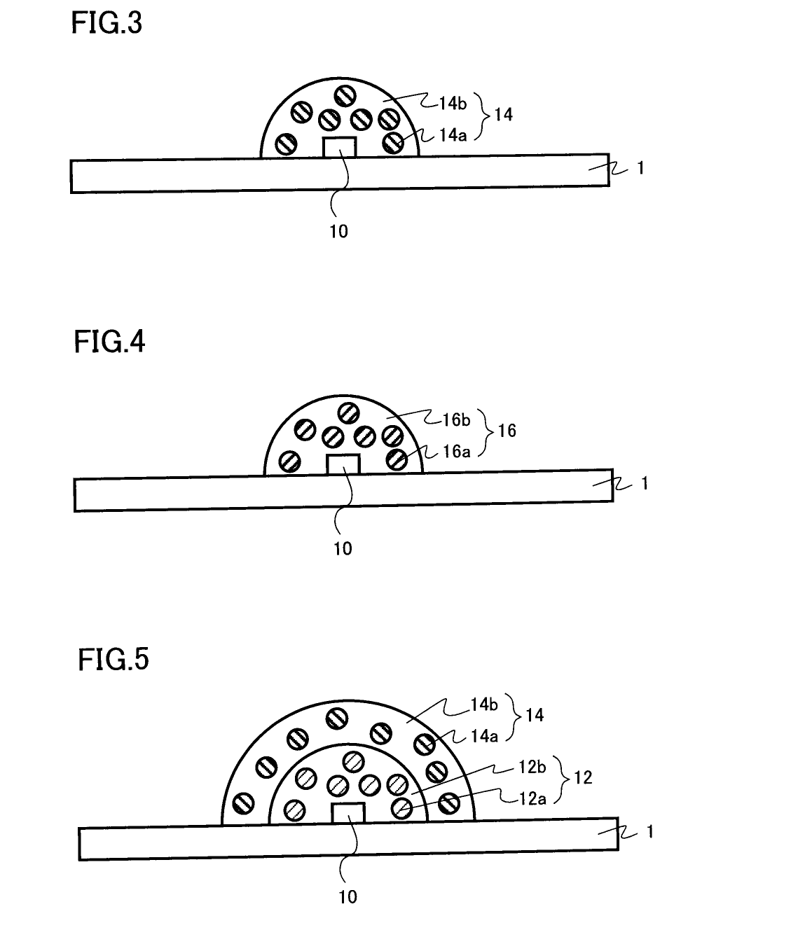

FIG. 3 is a schematic cross-sectional view of the light emitting device of this embodiment.

The light emitting device of this embodiment includes a light emitting element 10 and a color conversion layer 14. The light emitting element 10 is mounted on a substrate 1. For example, a highly reflective material is used to form the substrate.

The light emitting element 10 is configured to emit near-ultraviolet light or blue light as exciting light. For example, when the exciting light is near-ultraviolet light, the light emitting device emits green light. Alternatively, for example, when the exciting light is blue light, the light emitting device emits blue-green light.

The light emitting device of this embodiment differs from that of the first embodiment in that it has the color conversion layer (green color conversion layer) 14 instead of the color conversion layer (yellow color conversion layer) 12. The color conversion layer 14 is dome-shaped and disposed in such a way that the light emitting element 10 is embedded in it.

The color conversion layer 14 includes a plurality of phosphor (green phosphor) particles 14a and a resin 14b surrounding the phosphor particles 14a. The thickness of the color conversion layer 14 is, for example, from 0.1 mm to 3.0 mm.

In this embodiment, the phosphor particles 14a have a chemical composition expressed by formula (2) below, which represents a green phosphor capable of converting the exciting light to green light.

(Sr₁₋ₓ₂Euₓ₂)ₐ₂AlSi_{b2}O_{c2}N_{d2} (2)

(In formula (2), x2, a2, b2, c2, and d2 satisfy the following relations: 0<x2≦0.2, 0.93<a2<1.3, 4.0<b2<5.8, 0.6<c2<1.0, and 6.0<d2<11.)

In this embodiment, the phosphor particles 14a emit green light with a peak wavelength of 480 nm to less than 530 nm. In this embodiment, the phosphor particles 14a are made of an oxynitride phosphor containing silicon (Si), aluminum (Al), and strontium (Sr), which is what is called a sialon phosphor. This phosphor has a crystal structure substantially the same as that of Sr₃Si₁₃Al₃O₂N₂₁ and is activated with Eu. The sialon phosphor emits light with high efficiency.

The phosphor particles 14a preferably have a particle size of 1 μm to 25 μm. The phosphor particles 14a more preferably have a particle size of 3 μm or more, even more preferably 5 μm or more.

In this embodiment, if the volume concentration of the green phosphor in the color conversion layer 14 is more than 7%, the luminous efficiency will decrease as in the first embodiment using the yellow phosphor.

The volume concentration of the phosphor (green phosphor) particles 14a in the color conversion layer 14 is 7% or less. The volume concentration of the green phosphor in the color conversion layer 14 is preferably 7% or less in order to suppress the reduction of the luminous efficiency. The volume concentration is more preferably 6% or less, even more preferably 4% or less.

The volume concentration of the green phosphor in the color conversion layer 14 is preferably 0.2% or more so that the color conversion layer 14 can be prevented from being too thick and the size of the light emitting device can be kept suitable for practical use.

In order to suppress the reduction of the luminous efficiency, the volume concentration of the phosphor is preferably set relatively low also when the light emitting device emits light with the same chromaticity. Therefore, the amount of europium (Eu) as an activator is preferably set relatively large, and the relation 0.1≦x1≦0.2 is preferred.

According to the light emitting device of this embodiment, the volume concentration of the green phosphor in the color conversion layer is limited to a certain level or lower. Therefore, the luminous efficiency reduction caused by the scattering of the exciting light is suppressed. This makes it possible to provide a light emitting device with an improved luminous efficiency.

### Third Embodiment

The light emitting device of this embodiment includes a light emitting element emitting near-ultraviolet light or blue light as exciting light, a red color conversion layer including a red phosphor and a resin, the red phosphor represented by formula (3) and being capable of converting the exciting light to red light, the resin surrounding the red phosphor, the red color conversion layer containing the red phosphor at a volume concentration of 7% or less. This device has the same features as those of the first embodiment, except that it has the red color conversion layer containing the red phosphor instead of the yellow color conversion layer containing the yellow phosphor. Therefore, a detailed description of the same features as those of the first embodiment will be omitted.

(Sr₁₋ₓ₃Euₓ₃)ₐ₃AlSi_{b3}O_{c3}N_{d3} (3)

(In formula (3), x3, a3, b3, c3, and d3 satisfy the following relations: 0<x3≦0.2, 0.6<a3<0.95, 2.0<b3<3.9, 0.25<c3<0.45, and 4.0<d3<5.0.)

FIG. 4 is a schematic cross-sectional view of the light emitting device of this embodiment.

The light emitting device of this embodiment includes a light emitting element 10 and a color conversion layer 16. The light emitting element 10 is mounted on a substrate 1. For example, a highly reflective material is used to form the substrate.

The light emitting element 10 is configured to emit near-ultraviolet light or blue light as exciting light. For example, when the exciting light is near-ultraviolet light, the light emitting device emits red light. Alternatively, for example, when the exciting light is blue light, the light emitting device emits violet light.

The light emitting device of this embodiment differs from that of the first embodiment in that it has the color conversion layer (red color conversion layer) 16 instead of the color conversion layer (yellow color conversion layer) 12. The color conversion layer 16 is dome-shaped and disposed in such a way that the light emitting element 10 is embedded in it.

The color conversion layer 16 includes a plurality of phosphor (red phosphor) particles 16a and a resin 16b surrounding the phosphor particles 16a. The thickness of the color conversion layer 16 is, for example, from 0.1 mm to 3.0 mm.

In this embodiment, the phosphor particles 16a have a chemical composition expressed by formula (3) below, which represents a red phosphor capable of converting the exciting light to red light.

(Sr₁₋ₓ₃Euₓ₃)ₐ₃AlSi_{b3}O_{c3}N_{d3} (3)

(In formula (3), x3, a3, b3, c3, and d3 satisfy the following relations: 0<x3≦0.2, 0.6<a3<0.95, 2.0<b3<3.9, 0.25<c3<0.45, and 4.0<d3<5.0.)

In this embodiment, the phosphor particles 16a emit red light with a peak wavelength of 600 nm to less than 760 nm. In this embodiment, the phosphor particles 16a are made of an oxynitride phosphor containing silicon (Si), aluminum (Al), and strontium (Sr), which is what is called a sialon phosphor. This phosphor has a crystal structure substantially the same as that of Sr₂Si₇Al₃ON₁₃ and is activated with Eu. The sialon phosphor emits light with high efficiency.

The phosphor particles 16a preferably have a particle size of 1 μm to 25 μm. The phosphor particles 16a more preferably have a particle size of 3 μm or more, even more preferably 5 μm or more.

In this embodiment, if the volume concentration of the red phosphor in the color conversion layer 16 is more than 7%, the luminous efficiency will also decrease as in the first embodiment using the yellow phosphor.

The volume concentration of the phosphor (red phosphor) particles 16a in the color conversion layer 16 is 7% or less.

The volume concentration of the red phosphor in the color conversion layer 16 is preferably 7% or less in order to suppress the reduction of the luminous efficiency. The volume concentration is more preferably 6% or less, even more preferably 4% or less.

The volume concentration of the red phosphor in the color conversion layer 16 is preferably 0.2% or more so that the color conversion layer 16 can be prevented from being too thick and the size of the light emitting device can be kept suitable for practical use.

In order to suppress the reduction of the luminous efficiency, the volume concentration of the phosphor is preferably set relatively low also when the light emitting device emits light with the same chromaticity. Therefore, the amount of europium (Eu) as an activator is preferably set relatively large, and the relation 0.1≦x1≦0.05 is preferred.

According to the light emitting device of this embodiment, the volume concentration of the red phosphor in the color conversion layer is limited to a certain level or lower. Therefore, the luminous efficiency reduction caused by the scattering of the exciting light is suppressed. This makes it possible to provide a light emitting device with an improved luminous efficiency.

### Fourth Embodiment

The light emitting device of this embodiment has the same features as those of the first embodiment, except that it further includes a green color conversion layer (a second color conversion layer) including a green phosphor and a resin, the green phosphor represented by formula (2) and being capable of converting the exciting light to green light, the resin surrounding the green phosphor, the green color conversion layer containing the green phosphor at a volume concentration of 7% or less. Therefore, a detailed description of the same features as those of the first embodiment will be omitted.

(Sr₁₋ₓ₂Euₓ₂)ₐ₂AlSi_{b2}O_{c2}N_{d2} (2)

(In formula (2), x2, a2, b2, c2, and d2 satisfy the following relations: 0<x2≦0.2, 0.93<a2<1.3, 4.0<b2<5.8, 0.6<c2<1.0, and 6.0<d2<11.)

FIG. 5 is a schematic cross-sectional view of the light emitting device of this embodiment. This light emitting device is, for example, a white light emitting device.

The light emitting device of this embodiment differs from that of the first embodiment in that it has the color conversion layer (the second color conversion layer (green color conversion layer)) 14 provided on the color conversion layer (the first color conversion layer (yellow color conversion layer)) 12. The color conversion layer 14 is the same as that in the second embodiment.

According to the light emitting device of this embodiment, the volume concentrations of the yellow and green phosphors in the color conversion layers are each limited to a certain level or lower. Therefore, the luminous efficiency reduction caused by the scattering of the exciting light is suppressed. This makes it possible to provide a light emitting device with an improved luminous efficiency.

The use of the green phosphor also makes the chromaticity control range wider than that in the first embodiment.

### Fifth Embodiment

The light emitting device of this embodiment has the same features as those of the first embodiment, except that it further includes a red color conversion layer (third color conversion layer) including a red phosphor and a resin, the red phosphor represented by formula (3) and being capable of converting the exciting light to red light, the resin surrounding the red phosphor, the red color conversion layer containing the red phosphor at a volume concentration of 7% or less. Therefore, a detailed description of the same features as those of the first embodiment will be omitted.

(Sr₁₋ₓ₃Euₓ₃)ₐ₃AlSi_{b3}O_{c3}N_{d3} (3)

(In formula (3), x3, a3, b3, c3, and d3 satisfy the following relations: 0<x3≦0.2, 0.6<a3<0.95, 2.0<b3<3.9, 0.25<c3<0.45, and 4.0<d3<5.0.)

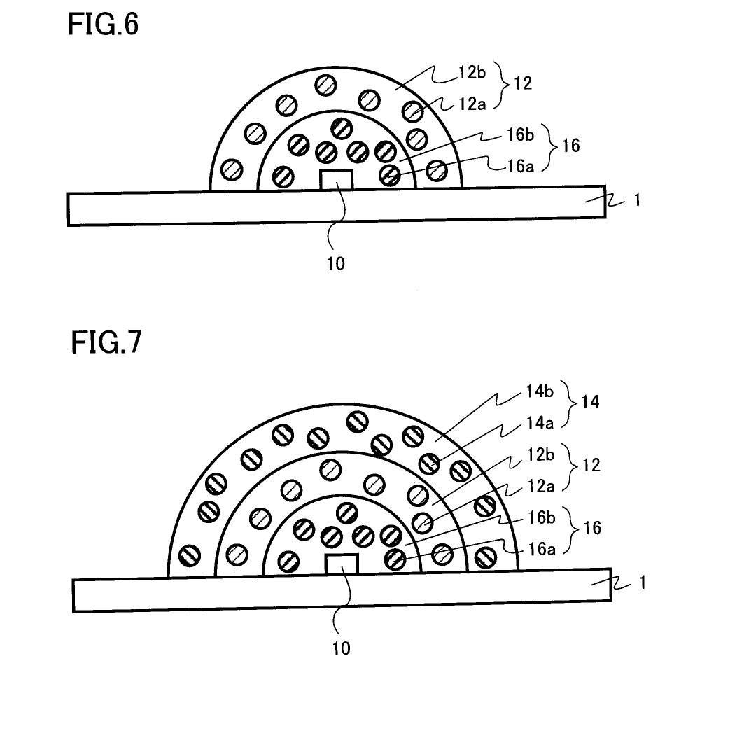

FIG. 6 is a schematic cross-sectional view of the light emitting device of this embodiment. This light emitting device is, for example, a white light emitting device.

The light emitting device of this embodiment differs from that of the first embodiment in that it has the color conversion layer (the third color conversion layer (red color conversion layer)) 16 provided under the color conversion layer (the first color conversion layer (yellow color conversion layer)) 12, in other words, between the light emitting element 10 and the color conversion layer 12. The color conversion layer 16 is the same as that in the third embodiment.

According to the light emitting device of this embodiment, the volume concentrations of the yellow and red phosphors in the color conversion layers are each limited to a certain level or lower. Therefore, the luminous efficiency reduction caused by the scattering of the exciting light is suppressed. This makes it possible to provide a light emitting device with an improved luminous efficiency.

The use of the red phosphor also makes the chromaticity control range wider than that in the first embodiment.

### Sixth Embodiment

FIG. 7 is a schematic cross-sectional view of the light emitting device of this embodiment. This light emitting device is, for example, a white light emitting device.

The light emitting device of this embodiment differs from that of the first embodiment in that it has a color conversion layer (the third color conversion layer (red color conversion layer)) 16 provided under the color conversion layer (the first color conversion layer (yellow color conversion layer)) 12 and also has a color conversion layer (the second color conversion layer (green color conversion layer)) 14 provided on the color conversion layer (the first color conversion layer (yellow color conversion layer)) 12. The color conversion layer 14 is the same as that in the second embodiment. The color conversion layer 16 is the same as that in the third embodiment.

The color conversion layer (the third color conversion layer (red color conversion layer)) 16 includes a plurality of phosphor (red phosphor) particles 16a and a resin 16b surrounding the phosphor particles 16a. The color conversion layer (the first color conversion layer (yellow color conversion layer)) 12 includes a plurality of phosphor (yellow phosphor) particles 12a and a resin 12b surrounding the phosphor particles 12a. The color conversion layer (the second color conversion layer (green color conversion layer)) 14 includes a plurality of phosphor (green phosphor) particles 14a and a resin 14b surrounding the phosphor particles 14a.

According to the light emitting device of this embodiment, the volume concentrations of the yellow, red, and green phosphors in the color conversion layers are each limited to a certain level or lower. Therefore, the luminous efficiency reduction caused by the scattering of the exciting light is suppressed. This makes it possible to provide a light emitting device with an improved luminous efficiency.

The use of the red and green phosphors also makes the chromaticity control range wider than that in the first embodiment.

### Seventh Embodiment

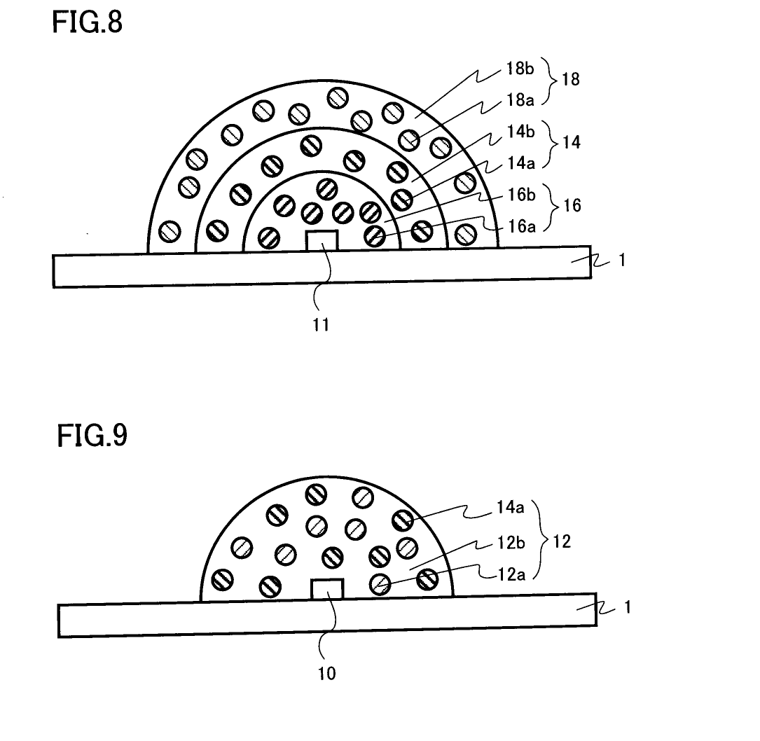

FIG. 8 is a schematic cross-sectional view of the light emitting device of this embodiment. This light emitting device is, for example, a white light emitting device.

The light emitting device of this embodiment includes a light emitting element 11 configured to emit near-ultraviolet light as exciting light, and a color conversion layer 16, a color conversion layer 14, and a color conversion layer (blue color conversion layer) 18, which are provided on the light emitting element 11. The color conversion layer 14 is the same as that in the second embodiment. The color conversion layer 16 is the same as that in the third embodiment.

The color conversion layer 16 includes a plurality of phosphor (red phosphor) particles 16a and a resin 16b surrounding the phosphor particles 16a. The color conversion layer 14 includes a plurality of phosphor (green phosphor) particles 14a and a resin 14b surrounding the phosphor particles 14a. The color conversion layer (blue color conversion layer) 18 includes a plurality of phosphor (blue phosphor) particles 18a and a resin 18b surrounding the phosphor particles 18a. The blue phosphor is, for example, BaMgAl₁₀O₁₇:Eu. It will be understood that the blue phosphor is not limited to this material.

According to the light emitting device of this embodiment, the volume concentrations of the red and green phosphors in the color conversion layers are each limited to a certain level or lower. Therefore, the luminous efficiency reduction caused by the scattering of the exciting light is suppressed. This makes it possible to provide a light emitting device with an improved luminous efficiency.

The use of the red, green, and blue phosphors also makes the chromaticity control range wider than that in the first embodiment.

### Eighth Embodiment

The light emitting device of this embodiment has the same features as those of the first embodiment, except that the first color conversion layer contains a green phosphor represented by formula (2) below and capable of converting the exciting light to green light and that the sum of the volume concentrations of the yellow and green phosphors is 7% or less. Therefore, a detailed description of the same features as those of the first embodiment will be omitted.

(Sr₁₋ₓ₂Euₓ₂)ₐ₂AlSi_{b2}O_{c2}N_{d2} (2)

(In formula (2), x2, a2, b2, c2, and d2 satisfy the following relations: 0<x2≦0.2, 0.93<a2<1.3, 4.0<b2<5.8, 0.6<c2<1.0, and 6.0<d2<11.)

FIG. 9 is a schematic cross-sectional view of the light emitting device of this embodiment. This light emitting device is, for example, a white light emitting device.

The color conversion layer 12 includes a plurality of phosphor (yellow phosphor) particles 12a, a plurality of phosphor (green phosphor) particles 14a, and a resin 12b surrounding the phosphor particles 12a and 14a. The phosphor (yellow phosphor) particles 12a are the same as those in the first embodiment. The phosphor (green phosphor) particles 14a are the same as those in the second embodiment.

The sum of the volume concentrations of the phosphor (yellow phosphor) particles 12a and the phosphor (green phosphor) particles 14a is 7% or less.

According to the light emitting device of this embodiment, the volume concentration of the yellow and green phosphors in the color conversion layer is limited to a certain level or lower. Therefore, the luminous efficiency reduction caused by the scattering of the exciting light is suppressed. This makes it possible to provide a light emitting device with an improved luminous efficiency.

The use of the green phosphor also makes the chromaticity control range wider than that in the first embodiment. The addition of the yellow and green phosphors to the same color conversion layer makes it easy to produce the light emitting device.

### Ninth Embodiment

The light emitting device of this embodiment has the same features as those of the first embodiment, except that the first color conversion layer contains a red phosphor represented by formula (3) below and capable of converting the exciting light to red light and that the sum of the volume concentrations of the yellow and red phosphors is 7% or less. Therefore, a detailed description of the same features as those of the first embodiment will be omitted.

(Sr₁₋ₓ₃Euₓ₃)ₐ₃AlSi_{b3}O_{c3}N_{d3} (3)

(In formula (3), x3, a3, b3, c3, and d3 satisfy the following relations: 0<x3≦0.2, 0.6<a3<0.95, 2.0<b3<3.9, 0.25<c3<0.45, and 4.0<d3<5.0.)

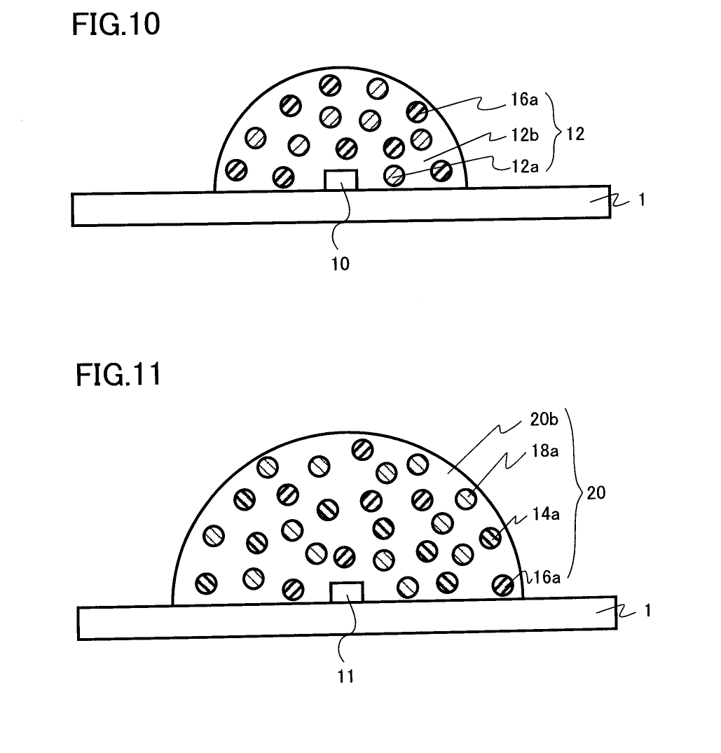

FIG. 10 is a schematic cross-sectional view of the light emitting device of this embodiment. This light emitting device is, for example, a white light emitting device.

The color conversion layer 12 includes a plurality of phosphor (yellow phosphor) particles 12a, a plurality of phosphor (red phosphor) particles 16a, and a resin 12b surrounding the phosphor particles 12a and 16a. The phosphor (yellow phosphor) particles 12a are the same as those in the first embodiment. The phosphor (red phosphor) particles 16a are the same as those in the third embodiment.

The sum of the volume concentrations of the phosphor (yellow phosphor) particles 12a and the phosphor (red phosphor) particles 16a is 7% or less.

According to the light emitting device of this embodiment, the volume concentration of the yellow and red phosphors in the color conversion layer is limited to a certain level or lower. Therefore, the luminous efficiency reduction caused by the scattering of the exciting light is suppressed. This makes it possible to provide a light emitting device with an improved luminous efficiency.

The use of the red phosphor also makes the chromaticity control range wider than that in the first embodiment. The addition of the yellow and red phosphors to the same color conversion layer makes it easy to produce the light emitting device.

### Tenth Embodiment

FIG. 11 is a schematic cross-sectional view of the light emitting device of this embodiment. This light emitting device is, for example, a white light emitting device.

The light emitting device of this embodiment includes a light emitting element 11 configured to emit near-ultraviolet light as exciting light and a color conversion layer 20 provided on the light emitting element 11. The color conversion layer 20 includes a plurality of phosphor (green phosphor) particles 14a, a plurality of phosphor (red phosphor) particles 16a, a plurality of phosphor (blue phosphor) particles 18a, and a resin 20b surrounding the phosphor particles 14a, 16a, and 18a. The phosphor (green phosphor) particles 14a are the same as those in the second embodiment. The phosphor (red phosphor) particles 16a are the same as those in the third embodiment.

The sum of the volume concentrations of the phosphor (green phosphor) particles 14a and the phosphor (red phosphor) particles 16a is 7% or less.

According to the light emitting device of this embodiment, the volume concentration of the green and red phosphors in the color conversion layer is limited to a certain level or lower. Therefore, the luminous efficiency reduction caused by the scattering of the exciting light is suppressed. This makes it possible to provide a light emitting device with an improved luminous efficiency.

The use of the red, green, and blue phosphors also makes the chromaticity control range wider than that in the first embodiment. The addition of the green, red, and blue phosphors to the same color conversion layer makes it easy to produce the light emitting device.

Embodiments have been described with reference to exemplary cases where an AlGaInN LED having a GaInN light emitting layer is used. Any LED may be used, in which a III-V compound semiconductor such as aluminum gallium indium nitride (AlGaInN) or a II-VI compound semiconductor such as magnesium zinc oxide (MgZnO) is used as a light emitting layer (active layer).

For example, the III-V compound semiconductor for use as the light emitting layer is a nitride semiconductor containing at least one selected from the group consisting of Al, Ga, and In. This nitride semiconductor is specifically represented by AlₓGa_{y}In_{(1-x-y)}N (0≦x≦1, 0≦y≦1, 0≦(x+y)≦1. Examples of this nitride semiconductor include all of binary semiconductors such as AlN, GaN, and InN, ternary semiconductors such as AlₓGa₍₁₋ₓ₎N (0<x<1), AlₓIn_{(1-x )}N (0<x<1), and Ga_{y}In_{(1-y)}N (0<y<1), and quaternary semiconductors containing all these elements. The emission peak wavelength is determined in the range of ultraviolet to blue based on the composition ratio x:y:(1−x−y) (Al:Ga:In). The group III element may also be partially replaced by boron (B), thallium (Tl), or the like. The group V element N may also be partially replaced by phosphorus (P), arsenic (As), antimony (Sb), bismuth (Bi), or the like.

The II-VI compound semiconductor for use as the light emitting layer may also be an oxide semiconductor containing at least one of Mg and Zn. Specifically, the II-VI compound semiconductor may be represented by Mg_{z}Zn_{(1-z)}O (0≦z≦1). The emission peak wavelength is determined in the ultraviolet region based on the composition ratio z:(1-z) (Mg:Zn).

The light emitting element may be not only an LED but also any other light source emitting near-ultraviolet light or blue light. For example, a laser diode (LD) may also be used.

In the above description, silicone resin is shown as an example of the resin for the color conversion layer. However, the resin may be any material having high transparency to the exciting light and high heat resistance. Examples of such a material that may be used include not only silicone resin but also epoxy resin, urea resin, fluororesin, acrylic resin, polyimide resin, epoxy group-containing polydimethylsiloxane derivatives, oxetane resin, cycloolefin resin, and the like. In particular, silicone resin and epoxy resin are preferably used because they are easily available, easy to handle, and inexpensive.

In the exemplary cases shown above, the color conversion layer is dome-shaped. However, the dome-shaped color conversion layer is non-limiting. The color conversion layer may have any other shape that allows the light emitting element (including its side) to be covered with the layer, such as a cup shape.

A transparent resin layer containing no phosphor may also be provided between the light emitting element and the color conversion layer, between the color conversion layers, or on the outermost periphery of the color conversion layer.

While certain embodiments have been described, these embodiments have been presented by way of example only, and are not intended to limit the scope of the inventions. Indeed, the light emitting device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A light emitting device comprising:
a light emitting element emitting near-ultraviolet light or blue light as exciting light; and
a yellow color conversion layer including a yellow phosphor and a resin, the yellow phosphor represented by formula (1) and being capable of converting the exciting light to yellow light, the resin surrounding the yellow phosphor, the yellow color conversion layer containing the yellow phosphor at a volume concentration of at most 7%, the yellow color conversion layer having a region whose cross section parallel to a light emitting surface of the light emitting element has an area larger than the light emitting surface,
(Sr₁₋ₓ₁Ceₓ₁)ₐ₁AlSi_{b1}O_{c1}N_{d1} (1)
wherein x1, a1, b1, c1, and d1 satisfy following relations: 0<x1≦0.1, 0.6<a1<0.95, 2.0<b1<3.9, 0<c1<0.45, and 4.0<d1<5.0.

2. The device according to claim 1, wherein the formula (1) satisfies 0.05≦x1≦0.1.

3. The device according to claim 1, wherein the exciting light is blue light, and when a chromaticity is expressed as (Cx, Cy) coordinates on a CIE chromaticity diagram, the device emits light with the chromaticity satisfying 0.30≦Cx≦0.48, 0.30≦Cy≦0.44.

4. The device according to claim 1, further comprising:
a green color conversion layer including a green phosphor and a resin, the green phosphor represented by formula (2) and being capable of converting the exciting light to green light, the resin surrounding the green phosphor, the green color conversion layer containing the green phosphor at a volume concentration of at most 7%, the green color conversion layer having a region whose cross section parallel to the light emitting surface of the light emitting element has an area larger than the light emitting surface,
(Sr₁₋ₓ₂Euₓ₂)ₐ₂AlSi_{b2}O_{c2}N_{d2} (2)
wherein x2, a2, b2, c2, and d2 satisfy following relations: 0<x2≦0.2, 0.93<a2<1.3, 4.0<b2<5.8, 0.6<c2<1.0, and 6.0<d2<11.

5. The device according to claim 1, further comprising:
a red color conversion layer including a red phosphor and a resin, the red phosphor represented by formula (3) and being capable of converting the exciting light to red light, the resin surrounding the red phosphor, the red color conversion layer containing the red phosphor at a volume concentration of at most 7%, the red color conversion layer having a region whose cross section parallel to the light emitting surface of the light emitting element has an area larger than the light emitting surface,
(Sr₁₋ₓ₃Euₓ₃)ₐ₃AlSi_{b3}O_{c3}N_{d3} (3)
wherein x3, a3, b3, c3, and d3 satisfy following relations: 0<x3≦0.2, 0.6<a3<0.95, 2.0<b3<3.9, 0.25<c3<0.45, and 4.0<d3<5.0.

6. The device according to claim 1, wherein the yellow color conversion layer contains a green phosphor represented by formula (2), the green phosphor is capable of converting the exciting light to green light, and the sum of the volume concentrations of the yellow and green phosphors is at most 7%,
(Sr₁₋ₓ₂Euₓ₂)ₐ₂AlSi_{b2}O_{c2}N_{d2} (2)
wherein x2, a2, b2, c2, and d2 satisfy following relations: 0<x2≦0.2, 0.93<a2<1.3, 4.0<b2<5.8, 0.6<c2<1.0, and 6.0<d2<11.

7. The device according to claim 1, wherein the yellow color conversion layer contains a red phosphor represented by formula (3), the red phosphor is capable of converting the exciting light to red light, and the sum of the volume concentrations of the yellow and red phosphors is at most 7%,
(Sr₁₋ₓ₃Euₓ₃)ₐ₃AlSi_{b3}O_{c3}N_{d3} (3)
wherein x3, a3, b3, c3, and d3 satisfy following relations: 0<x3≦0.2, 0.6<a3<0.95, 2.0<b3<3.9, 0.25<c3<0.45, and 4.0<d3<5.0.

8. The device according to claim 1, wherein the light emitting element is an LED.

9. The device according to claim 1, wherein the yellow phosphor has a particle size of 1 μm to 25 μm.

10. The device according to claim 1, further comprising:
a green color conversion layer including a green phosphor and a resin, the green phosphor represented by formula (2) and being capable of converting the exciting light to green light, the resin surrounding the green phosphor, the green color conversion layer containing the green phosphor at a volume concentration of at most 7%, the green color conversion layer having a region whose cross section parallel to a light emitting surface of the light emitting element has an area larger than the light emitting surface,
(Sr₁₋ₓ₂Euₓ₂)ₐ₂AlSi_{b2}O_{c2}N_{d2} (2)
wherein x2, a2, b2, c2, and d2 satisfy following relations: 0<x2≦0.2, 0.93<a2<1.3, 4.0<b2<5.8, 0.6<c2<1.0, and 6.0<d2<11; and
a red color conversion layer including a red phosphor and a resin, the red phosphor represented by formula (3) and being capable of converting the exciting light to red light, the resin surrounding the red phosphor, the red color conversion layer containing the red phosphor at a volume concentration of at most 7%, the red color conversion layer having a region whose cross section parallel to a light emitting surface of the light emitting element has an area larger than the light emitting surface,
(Sr₁₋ₓ₃Euₓ₃)ₐ₃AlSi_{b3}O_{c3}N_{d3} (3)
wherein x3, a3, b3, c3, and d3 satisfy following relations: 0<x3≦0.2, 0.6<a3<0.95, 2.0<b3<3.9, 0.25<c3<0.45, and 4.0<d3<5.0,
wherein the red color conversion layer, the yellow color conversion layer, and the green color conversion layer are disposed in this order from the light emitting element.

11. The device according to claim 2, wherein the exciting light is blue light, and when the chromaticity is expressed as (Cx, Cy) coordinates on a CIE chromaticity diagram, the device emits light with a chromaticity satisfying 0.30≦Cx≦0.48, 0.30≦Cy≦0.44.

12. The device according to claim 11, further comprising:
a green color conversion layer including a green phosphor and a resin, the green phosphor represented by formula (2) and being capable of converting the exciting light to green light, the resin surrounding the green phosphor, the green color conversion layer containing the green phosphor at a volume concentration of at most 7%, the green color conversion layer having a region whose cross section parallel to a light emitting surface of the light emitting element has an area larger than the light emitting surface,
(Sr₁₋ₓ₂Euₓ₂)ₐ₂AlSi_{b2}O_{c2}N_{d2} (2)
wherein x2, a2, b2, c2, and d2 satisfy following relations: 0<x2≦0.2, 0.93<a2<1.3, 4.0<b2<5.8, 0.6<c2<1.0, and 6.0<d2<11.

13. The device according to claim 11, further comprising:
a red color conversion layer including a red phosphor and a resin, the red phosphor represented by formula (3) and being capable of converting the exciting light to red light, the resin surrounding the red phosphor, the red color conversion layer containing the red phosphor at a volume concentration of at most 7%, the red color conversion layer having a region whose cross section parallel to a light emitting surface of the light emitting element has an area larger than the light emitting surface,
(Sr₁₋ₓ₃EUₓ₃)ₐ₃AlSi_{b3}O_{c3}N_{d3} (3)
wherein x3, a3, b3, c3, and d3 satisfy following relations: 0<x3≦0.2, 0.6<a3<0.95, 2.0<b3<3.9, 0.25<c3<0.45, and 4.0<d3<5.0.

14. The device according to claim 11, wherein the yellow color conversion layer contains a green phosphor represented by formula (2),
(Sr₁₋ₓ₂Euₓ₂)ₐ₂AlSi_{b2}O_{c2}N_{d2} (2)
wherein x2, a2, b2, c2, and d2 satisfy following relations: 0<x2≦0.2, 0.93<a2<1.3, 4.0<b2<5.8, 0.6<c2<1.0, and 6.0<d2<11 and capable of converting the exciting light to green light, and the sum of the volume concentrations of the yellow and green phosphors is at most 7%.

15. The device according to claim 11, wherein the yellow color conversion layer contains a red phosphor represented by formula (3),
(Sr₁₋ₓ₃Euₓ₃)ₐ₃AlSi_{b3}O_{c3}N_{d3} (3)
wherein x3, a3, b3, c3, and d3 satisfy following relations: 0<x3≦0.2, 0.6<a3<0.95, 2.0<b3<3.9, 0.25<c3<0.45, and 4.0<d3<5.0 and capable of converting the exciting light to red light, and the sum of the volume concentrations of the yellow and red phosphors is at most 7%.

16. A light emitting device comprising: a light emitting element emitting near-ultraviolet light or blue light as exciting light; and
a green color conversion layer including a green phosphor and a resin, the green phosphor represented by formula (2) and being capable of converting the exciting light to green light, the resin surrounding the green phosphor, the green color conversion layer containing the green phosphor at a volume concentration of at most 7%, the green color conversion layer having a region whose cross section parallel to a light emitting surface of the light emitting element has an area larger than the light emitting surface,
(Sr₁₋ₓ₂Euₓ₂)ₐ₂AlSi_{b2}O_{c2}N_{d2} (2)
wherein x2, a2, b2, c2, and d2 satisfy following relations: 0<x2≦0.2, 0.93<a2<1.3, 4.0<b2<5.8, 0.6<c2<1.0, and 6.0<d2<11.

17. The device according to claim 16, wherein the green color conversion layer contains a blue phosphor being capable of converting the exiting light to blue light and a red phosphor represented by formula (3):
(Sr₁₋ₓ₃Euₓ₃)ₐ₃AlSi_{b3}O_{c3}N_{d3} (3)
wherein x3, a3, b3, c3, and d3 satisfy following relations: 0<x3≦0.2, 0.6<a3<0.95, 2.0<b3<3.9, 0.25<c3<0.45, and 4.0<d3<5.0 and capable of converting the exciting light to red light, and the sum of the volume concentrations of the green and red phosphors is at most 7%,
wherein the exciting light is near-ultraviolet light.

18. A light emitting device comprising: a light emitting element emitting near-ultraviolet light or blue light as exciting light; and
a red color conversion layer including a red phosphor and a resin, the red phosphor represented by formula (3) and being capable of converting the exciting light to red light, the resin surrounding the red phosphor, the red color conversion layer containing the red phosphor at a volume concentration of at most 7%, the red color conversion layer having a region whose cross section parallel to a light emitting surface of the light emitting element has an area larger than the light emitting surface,
(Sr₁₋ₓ₃Euₓ₃)ₐ₃AlSi_{b3}O_{c3}N_{d3} (3)
wherein x3, a3, b3, c3, and d3 satisfy following relations: 0<x3≦0.2, 0.6<a3<0.95, 2.0<b3<3.9, 0.25<c3<0.45, and 4.0<d3<5.0.

19. The device according to claim 18, further comprising:
a green color conversion layer including a green phosphor and a resin, the green phosphor represented by formula (2) and being capable of converting the exciting light to green light, the resin surrounding the green phosphor, the green color conversion layer containing the green phosphor at a volume concentration of at most 7%, the green color conversion layer having a region whose cross section parallel to a light emitting surface of the light emitting element has an area larger than the light emitting surface,
(Sr₁₋ₓ₂Euₓ₂)ₐ₂AlSi_{b2}O_{c2}N_{d2} (2)
wherein x2, a2, b2, c2, and d2 satisfy following relations: 0<x2≦0.2, 0.93<a2<1.3, 4.0<b2<5.8, 0.6<c2<1.0, and 6.0<d2<11
a blue color conversion layer including a blue phosphor and a resin, the blue phosphor being capable of converting the exciting light to blue light, the resin surrounding the blue phosphor,
wherein the red color conversion layer, the green color conversion layer, and the blue color conversion layer are disposed in this order from the light emitting element.

20. The device according to claim 19, wherein the exciting light is near-ultraviolet light.
